(19) United States
(12) Patent Application Publication
(10) Pub. No.: US 2010/0118909 A1
(43) Pub. Date: May 13, 2010

(54) MINIATURE HIGH-POWER LASER DIODE DEVICE

(75) Inventors: Hsing-Chia Kuo, Kaohsiung (TW); Chuen-Fuu Wu, Kaohsiung (TW); Lung-Tien Wu, Kaohsiung (TW); Tze-Ching Yang, Kaohsiung (TW)

Correspondence Address: WPAT, PC;INTELLECTUAL PROPERTY ATTORNEYS, 2030 MAIN STREET, SUITE 1300, IRVINE, CA, 92614, US

(73) Assignee: METAL INDUSTRIES RESEARCH & DEVELOPMENT CENTRE, Kaohsiung (TW)

(21) Appl. No.: 12/345,965

(22) Filed: Dec. 30, 2008

(30) Foreign Application Priority Data
Nov. 7, 2008 (TW) 097143238

(51) Int. Cl. H01S 5/026

(52) U.S. Cl. 372/50.1

(57) ABSTRACT

The present invention provides a miniature high-power laser diode device, which includes a base, a laser chip, an optical fiber guider, and an optical fiber. The base has a groove and a disposing area, and the groove connects to the disposing area. The laser chip is disposed on the disposing area, and the optical fiber guider is disposed at the groove. The optical fiber is disposed in and through the optical fiber guider. The optical fiber has a first end connected to the laser chip. As a result of the cooperation between the optical fiber guider and the groove, the orientation of the optical fiber is simple and precise. The conventional thermal deformation and residual welding stress can be reduced, and the soldering flux applied in a conventional soldering and packaging process of the optical fiber can be omitted, so that the coupling efficiency, the yield, the stability of high power laser output, and the lifetime of the laser diode device of the present invention can be improved.

### BACKGROUND OF THE INVENTION

1. Field of the Invention

The present invention relates to a laser diode device, and more particularly to a miniature high-power laser diode device.

2. Description of the Related Art

In the prior art, generally, a high-power laser diode is packaged in a package housing so as to form a butterfly package, and then an optical fiber is fixed by a saddle mechanism, and then the optical fiber and the chip are optically coupled and oriented by using a laser welding machine (a laser hammering process).

A conventional laser welding machine mainly includes a power supply, a clamping and orienting device, and a controller. FIG. 1 is a schematic view of a conventional saddle mechanism for clamping and orienting an optical fiber. As shown in FIG. 1, in the prior art, an optical fiber 11 is disposed in and through an optical fiber guider 12, and then the optical fiber guider 12 is placed into a saddle mechanism 13, thereby facilitating the laser spot welding, optical coupling, and alignment. In this case, the following three steps need to be performed: placing the optical fiber guider 12 into the saddle mechanism 13, fixing the optical fiber guider 12 at the saddle mechanism 13 by laser spot welding (at welding spots P1 and P2), and moving, positioning, and aligning the optical fiber 11 in three-dimensional (X-Y-Z) directions.

However, the prior art has the following disadvantages. A butterfly type high-power laser diode device requires a thermoelectric cooler (TE-cooler) to ensure the stability of the laser chip, so the package housing thereof is large in volume, which hampers the miniaturization of the system. The optical fiber guider 12 needs to meet a precise positioning requirement when being placed into the saddle mechanism 13, as does the laser spot welding process, so as to achieve a high coupling efficiency. As a result, the high-power laser diode devices cannot be mass produced and the packaging cost is accordingly increased.

Therefore, there is a need to provide a miniature high-power laser diode device to solve the above problem.

### SUMMARY OF THE INVENTION

The present invention provides a miniature high-power laser diode device, which includes a base, a laser chip, an optical fiber guider, and an optical fiber. The base has a groove and a disposing area, and the groove connects to the disposing area. The laser chip is disposed on the disposing area, and the optical fiber guider is disposed at the groove. The optical fiber is disposed in and through the optical fiber guider. The optical fiber has a first end connected to the laser chip.

As a result of the cooperation between the optical fiber guider and the groove, the orientation of the optical fiber is simple and precise. The conventional thermal deformation and residual welding stress can be reduced, and the soldering flux applied in a conventional soldering and packaging process of the optical fiber can be omitted, so that the coupling efficiency, the yield, the stability of high power laser output, and the lifetime of the laser diode device of the present invention can be improved.

### BRIEF DESCRIPTION OF THE DRAWINGS

FIG. 1 is a schematic view of a conventional saddle mechanism for clamping and orienting an optical fiber;

FIG. 2 is a schematic view of a miniature high-power laser diode device according to the present invention;

FIG. 3 is a schematic view of an optical fiber guider disposed at a V-shaped groove according to the present invention;

FIG. 4 is a schematic view of an optical fiber guider disposed at a U-shaped groove according to the present invention;

FIG. 5 is a schematic view of an optical fiber guider with flat-plate-shaped side fins according to the present invention;

FIG. 6 is a schematic view of an optical fiber with a grinding angle according to the present invention;

FIG. 7 is a schematic view of a mini-butterfly type high-power laser diode device according to the present invention;

FIG. 8 is a schematic view of a relation between the grinding angle and coupling efficiency of an optical fiber according to the present invention; and

FIG. 9 is a schematic view of a miniature high-power laser diode module according to the present invention.

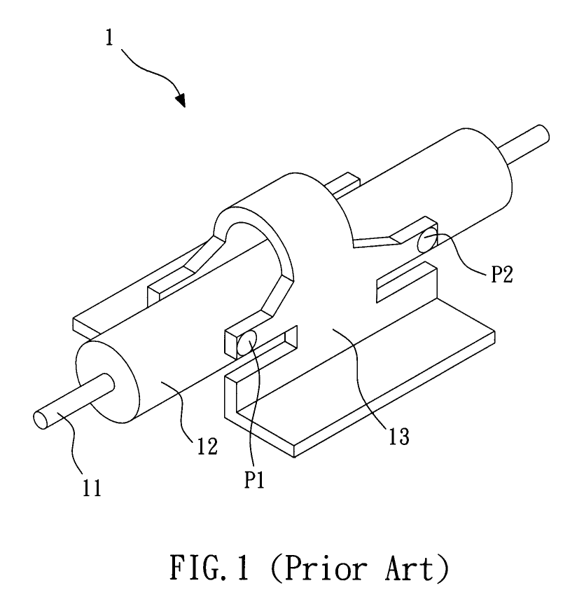

### DETAILED DESCRIPTION OF THE INVENTION

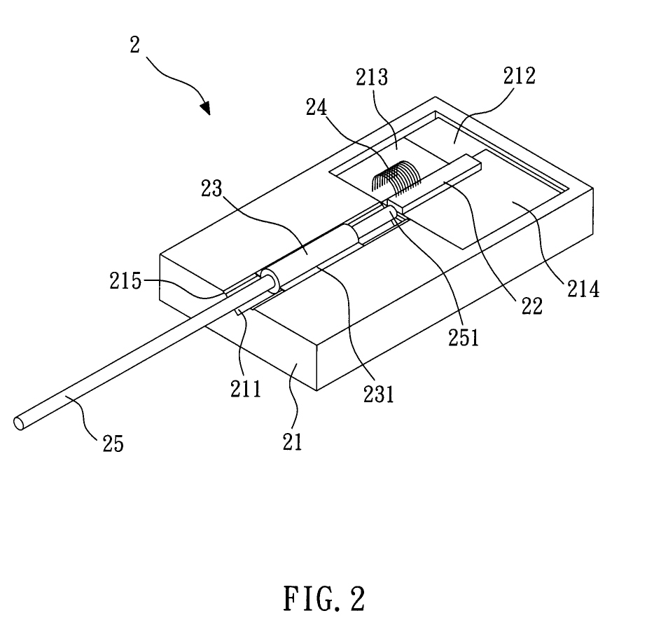

FIG. 2 is a schematic view of a miniature high-power laser diode device according to the present invention. Referring to FIG. 2, a miniature high-power laser diode device 2 is shown which includes a base 21, a laser chip 22, an optical fiber guider 23, a plurality of leads 24, and an optical fiber 25. The base 21 has a groove 211, a disposing area 212, a cathode electrode 213, and an anode electrode 214. The groove 211 connects the disposing area 212. The laser chip 22 is disposed on the disposing area 212. The optical fiber guider 23 is disposed at the groove 211.

The groove 211 comprises with supporting portions 215 on two sides of a rabbet thereof. The cathode electrode 213 and the anode electrode 214 are disposed on the disposing area 212. The cathode electrode 213 and the anode electrode 214 are respectively electrically connected to a cathode and an anode of the laser chip 22. In this embodiment, the laser chip 22 is adhered and electrically connected to the anode electrode 214. The leads 24 are electrically connected to the cathode of the laser chip 22 and the cathode electrode 213. The leads 24 are preferably gold wires.

The base 21 and the optical fiber guider 23 may be made of a KOVAR alloy, an INVAR alloy, or a tungsten carbide (WC) alloy as required. In this embodiment, the base 21 is made of an electrically insulating material (for example, the WC alloy). It should be noted that, if the base 21 is made of a conductive material (for example, the KOVAR or INVAR alloy), an insulating material must be disposed between the base 21 and the anode electrode 214, so that the base 21 is not electrically connected to the anode electrode 214.

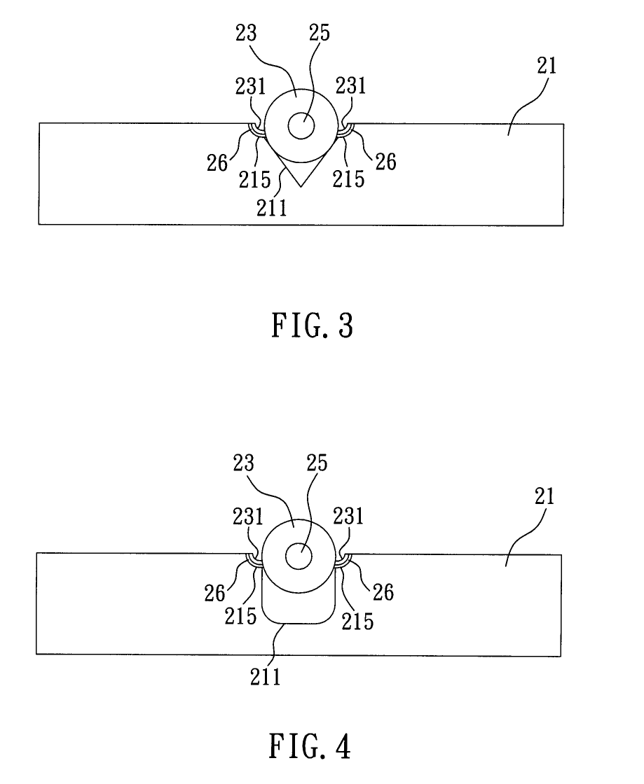

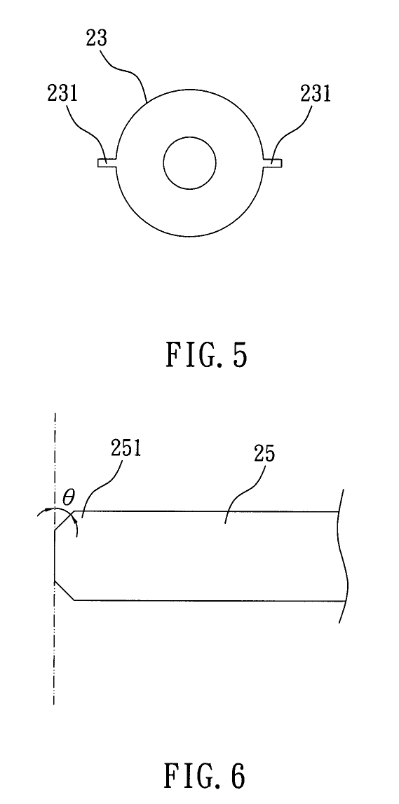

Referring to FIGS. 3 and 4, the groove 211 may be a V-shaped groove (as shown in FIG. 3) or a U-shaped groove (as shown in FIG. 4). The optical fiber guider 23 comprises two side fins 231. Preferably, the shape of the side fins 231 matches that of the supporting portions 215. The groove 211 of the base 21 is quite small, and each of the supporting portions 215 has an arc-shaped structure when viewed under a microscope, so the side fins 231 are preferably arc shaped. In other applications, the side fins 231 may be flat-plate shaped (as shown in FIG. 5). Preferably, a bonding material 26 is disposed between the supporting portions 215 and the side fins 231, so as to enhance the bonding between the supporting portions 215 and the side fins 231. The bonding material 26 is a gold-tin sheet (soldering), BAg-8 silver-copper sheet (brazing), a silver paste, or a polymer material containing copper/silver particles.

The optical fiber 25 is disposed in and through the optical fiber guider 23. The optical fiber 25 may be a single-mode optical fiber or a multimode optical fiber. The optical fiber 25 has a first end 251 connected to the laser chip 22. The first end 251 of the optical fiber 25 is formed with a grinding angle θ at a periphery thereof (as shown in FIG. 6). Preferably, the grinding angle θ is 20° to 30°.

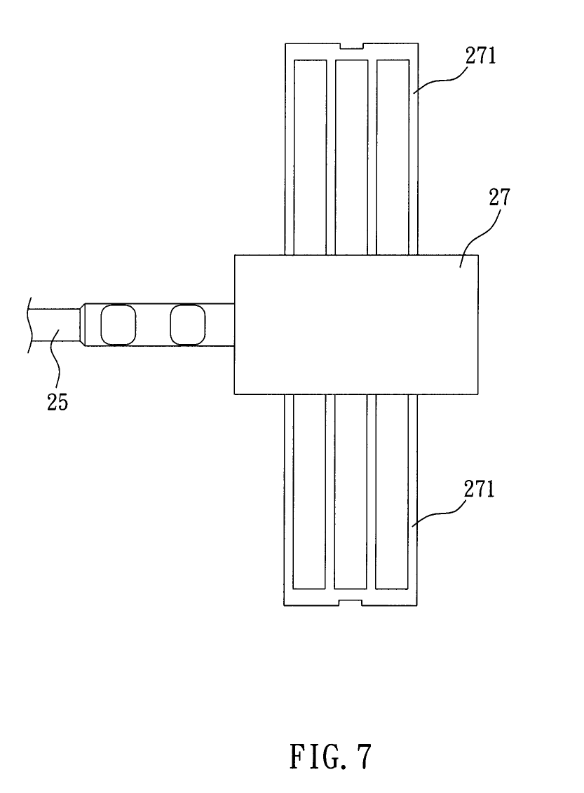

FIG. 7 is a schematic view of a mini-butterfly type high-power laser diode device according to the present invention. As shown in FIGS. 2 and 7, in other applications, a package housing 27 (for example, a mini-butterfly package housing) may be used to package the base 21, the laser chip 22, the optical fiber guider 23, and the optical fiber 25, so as to form a mini-butterfly type high-power laser diode device.

A process for manufacturing the miniature high-power laser diode device of the present invention is illustrated below by taking the mini-butterfly type high-power laser diode device as an example. Firstly, the base 21 is placed into the package housing 27, and connected to the package housing 27 through soldering process. Next, the laser chip 22 is adhered and electrically connected to the anode electrode 214. Afterwards, the leads 24 are connected to the cathode of the laser chip 22 and the cathode electrode 213 through wire bonding, and the cathode electrode 213 and the anode electrode 214 are each connected to corresponding electrodes of the package housing 27 (conducted to pins 271 at an exterior of the package housing 27). Then, the optical fiber 25 is placed into the optical fiber guider 23, and then the optical fiber guider 23 is placed into the groove 211. Then, the laser spot welding is performed on the optical fiber guider 23 (a laser hammering process), so as to adjust the coupling efficiency of the optical fiber 25 to the laser chip 22. Finally, a parallel resistance rolled welding process or a laser welding process is performed to seal the package housing 27 by seam welding, thereby completing the mini-butterfly type high-power laser diode device.

As shown in FIGS. 3 and 4, in the step of performing the laser spot welding on the optical fiber guider 23, firstly, a laser energy is applied to the side fins 231 to cause a slight deformation of the side fins 231, and thus, the angle and position of the side fins 231 are adjusted in such a way that the side fins 231 more tightly cooperate with the supporting portions 215 on two sides of the rabbet of the groove 211. Afterwards, the laser energy is applied between the side fins 231 and the supporting portions 215 or directly applied to the side fins 231 so as to heat and melt the bonding material 26, thereby bonding the supporting portions 215 and the side fins 231. Thus, through the present invention, the thermal deformation and residual welding stress of the conventional saddle mechanism and the optical fiber guider can be reduced, and the soldering flux applied in a conventional soldering and packaging process of the optical fiber can be omitted, thereby improving the coupling efficiency of the optical fiber and the lifetime of the laser diode device.

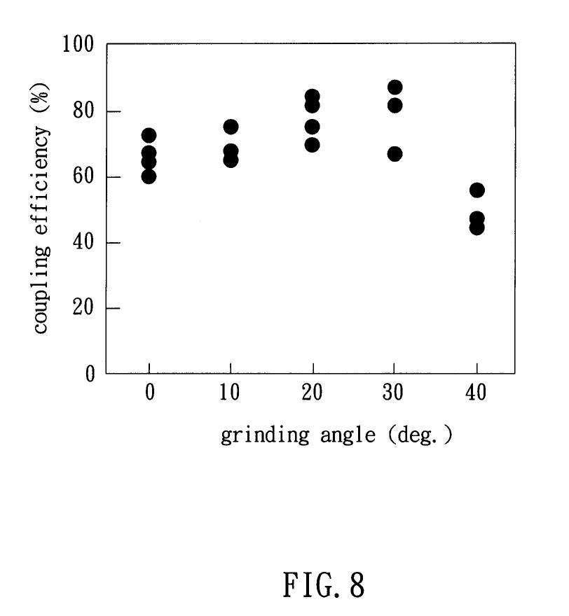

FIG. 8 is a schematic view of a relation between the grinding angle and coupling efficiency of an optical fiber according to the present invention. As shown in FIGS. 3, 6 and 8, after the angle and position of the side fins 231 are adjusted in the laser spot welding step and the supporting portions 215 and the side fins 231 are bonded together through heating and melting the bonding material 26, the grinding angle of the optical fiber 25 is also changed accordingly, so as to achieve the highest coupling efficiency. It can be clearly seen in the distribution of data points shown in FIG. 8 that, when the grinding angle falls between 20° and 30°, the miniature high-power laser diode device of the present invention has the highest coupling efficiency (up to about 85%), which proves that the miniature high-power laser diode device of the present invention does have an excellent coupling efficiency.

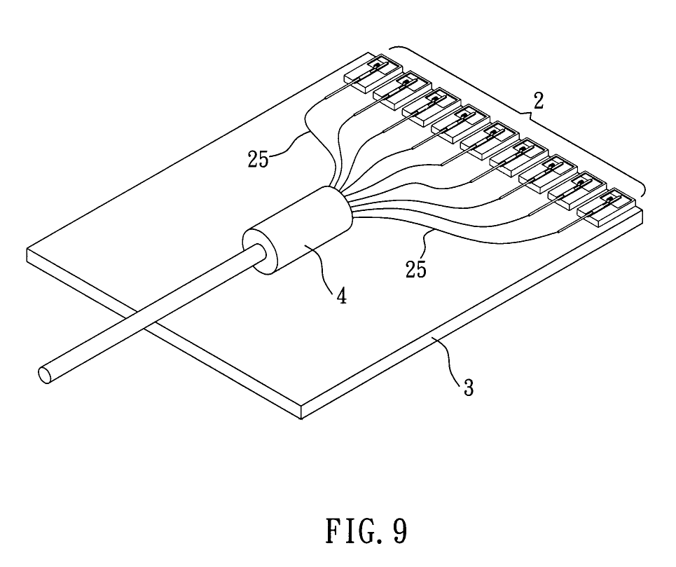

FIG. 9 is a schematic view of a miniature high-power laser diode module according to the present invention. As shown in FIGS. 2 and 9, in this embodiment, a plurality of miniature high-power laser diode devices 2 is disposed on a supporting substrate 3 (for example, a heat-dissipating substrate or a circuit board). The optical fibers 25 of the miniature high-power laser diode devices 2 are connected to a combiner 4, so that the lasers generated by the miniature high-power laser diode devices 2 are converged and output by the combiner 4, thereby meeting the requirements for setting the laser power.

To sum up, as a result of the cooperation of the optical fiber guider 23 and the groove 211, the orientation of the optical fiber 25 is simple and precise. The conventional thermal deformation and residual welding stress can be reduced, and the soldering flux applied in a conventional soldering and packaging process of the optical fiber can be omitted, so that the coupling efficiency, the yield, the stability of high power laser output, and the lifetime of the laser diode device of the present invention are improved.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A miniature high-power laser diode device, comprising:
a base, comprising a groove and a disposing area, wherein the groove connects to the disposing area;
a laser chip, disposed on the disposing area;
an optical fiber guider, disposed at the groove; and
an optical fiber, disposed in and through the optical fiber guider, and comprising a first end connected to the laser chip.

2. The miniature high-power laser diode device according to claim 1, wherein the base further comprises a cathode electrode and an anode electrode both disposed on the disposing area, wherein the cathode electrode and the anode electrode are respectively electrically connected to a cathode and an anode of the laser chip.

3. The miniature high-power laser diode device according to claim 2, is further comprising a plurality of leads electrically connected to the cathode of the laser chip and the cathode electrode.

4. The miniature high-power laser diode device according to claim 3, wherein the leads are gold wires and ribbons.

5. The miniature high-power laser diode device according to claim 2, further comprising an insulating material, disposed between the base and the anode electrode, wherein the base is made of a conductive material.

6. The miniature high-power laser diode device according to claim 5, wherein the base is made of a KOVAR or INVAR alloy.

7. The miniature high-power laser diode device according to claim 2, wherein the base is made of an electrically insulating material.

8. The miniature high-power laser diode device according to claim 7, wherein the base is made of a tungsten carbide (WC) alloy.

9. The miniature high-power laser diode device according to claim 1, wherein the groove is a U-shaped groove or a V-shaped groove.

10. The miniature high-power laser diode device according to claim 1, wherein the groove comprises supporting portions on two sides of a rabbet thereof, the optical fiber guider comprises two side fins, and a shape of the side fins matches that of the supporting portions.

11. The miniature high-power laser diode device according to claim 10, wherein the side fins are flat plate shaped.

12. The miniature high-power laser diode device according to claim 10, wherein the side fins are arc shaped.

13. The miniature high-power laser diode device according to claim 10, further comprising a bonding material disposed between the supporting portions and the side fins.

14. The miniature high-power laser diode device according to claim 13, wherein the bonding material is a gold-tin sheet, BAg-8 silver-copper sheet, or a silver paste.

15. The miniature high-power laser diode device according to claim 13, wherein the bonding material is a polymer material containing copper/silver particles.

16. The miniature high-power laser diode device according to claim 1, wherein the optical fiber is a single-mode optical fiber or a multimode optical fiber.

17. The miniature high-power laser diode device according to claim 1, wherein the first end of the optical fiber has a grinding angle at a periphery thereof.

18. The miniature high-power laser diode device according to claim 17, wherein the grinding angle is 20° to 30°.

19. The miniature high-power laser diode device according to claim 1, further comprising a package housing for packaging the base, the laser chip, the optical fiber guider, and the optical fiber.

20. The miniature high-power laser diode device according to claim 19, wherein the package housing is a mini-butterfly package housing.
